(19) United States
(12) Patent Application Publication
(10) Pub. No.: US 2026/0016508 A1
(43) Pub. Date: Jan. 15, 2026

(54) DIRECT ROTOR CURRENT MEASUREMENT FOR TRANSFORMER-FED WOUND ROTOR MACHINE

(71) Applicants: BorgWarner Inc., Auburn Hills, MI (US); UT-BATTELLE, LLC, Oak Ridge, TN (US)

(72) Inventors: Mostak Mohammad, Knoxville, TN (US); Shajjad Chowdhury, Knoxville, TN (US); Omer Caglar Onar, Knoxville, TN (US); Emrullah Aydin, Knoxville, TN (US); Frederick Michael Huscher, Hendersonville, NC (US); Gabriel Alejandro Domingues Olavarria, Lund (SE)

(21) Appl. No.: 19/269,916

(22) Filed: Jul. 15, 2025

Related U.S. Application Data
(60) Provisional application No. 63/671,543, filed on Jul. 15, 2024.

(51) Int. Cl. G01R 15/20; G01R 19/00

(52) U.S. Cl. CPC G01R 15/202; G01R 19/0092

(57) ABSTRACT

A wound rotor synchronous machine (WRSM) includes a rotary transformer. The rotary transformer has a primary coil and a secondary coil. A rotor is connected to a positive direct current (DC) output of the secondary coil and connected to a negative DC output of the secondary coil. The rotor includes a shaft. A winding is wound around the shaft. The winding includes a turn of one of the positive DC output and the negative DC output. A contactless sensor is disposed adjacent the winding and in communication with a controller.

### CROSS REFERENCE TO RELATED APPLICATIONS

This application claims the benefit of an earlier filing date from U.S. Provisional Application Ser. No. 63/671,543 filed Jul. 15, 2024, the entire disclosure of which is incorporated herein by reference.

This invention was made under CRADA No. NFE-22-09369 between BorgWarner Inc. and UT-Battelle, LLC, management and operating contractor for the Oak Ridge National Laboratory for the United States Department of Energy. The Government has certain rights in this invention.

### BACKGROUND OF THE INVENTION

Those of skill in the art will recognize that wound rotor synchronous machines (WRSMs) utilize a construction where a rotor is provided electrical energy through a rotary transformer. A rotor current is required to be provided to the WRSM in order to control operations of the WRSM. As the rotor current is provided interior to the WRSM, direct measurement of the rotor current to ensure the provided rotor current matches the commanded rotor current is not available in existing systems. Instead, existing systems estimate the rotor current using a measured current of one of a primary transformer coil and a stationary secondary coil of a rotary transformer for the WRSM.

### BRIEF DESCRIPTION OF THE INVENTION

Disclosed is an embodiment of a wound rotor synchronous machine (WRSM) including a rotary transformer. The rotary transformer has a primary coil and a secondary coil. A rotor is connected to a positive direct current (DC) output of the secondary coil and connected to a negative DC output of the secondary coil. The rotor includes a shaft. A winding is wound around the shaft. The winding includes a turn of one of the positive DC output and the negative DC output. A contactless sensor is disposed adjacent the winding and in communication with a controller.

Also disclosed is an embodiment of a method of detecting a rotor current of a wound rotor synchronous machine (WRSM) including measuring a magnetic field of a winding using a contactless Hall effect sensor. The winding is comprised of one of a positive direct current (DC) output of a secondary coil of a rotary transformer and a negative DC output of the secondary coil of the rotary transformer. The winding is wound around a shaft of the WRSM.

### BRIEF DESCRIPTION OF THE DRAWINGS

The following descriptions should not be considered limiting in any way. With reference to the accompanying drawings, like elements are numbered alike:

FIG. 1A is a schematic side view of a first wound rotor synchronous machine (WRSM) including a Hall effect rotor current sensor;

FIG. 1B is a schematic side view of a second wound rotor synchronous machine (WRSM) including a Hall effect rotor current sensor

FIG. 2 is a schematic top view of the WRSM of FIG. 1;

FIG. 3 is a schematic axial end view of a shaft of the WRSM of FIGS. 1 and 2;

FIG. 4 is partial schematic view of Hall effect sensor positioning of the WRSM of FIGS. 1-3;

FIG. 5 is a schematic top view of a WRSM including a Hall effect sensor spaced apart from the rotor using flux shielding; and

FIG. 6 is a schematic illustration of an alternate flux shielding including radial extensions.

### DETAILED DESCRIPTION OF THE INVENTION

A detailed description of one or more embodiments of the disclosed apparatus and method are presented herein by way of exemplification and not limitation with reference to the Figures.

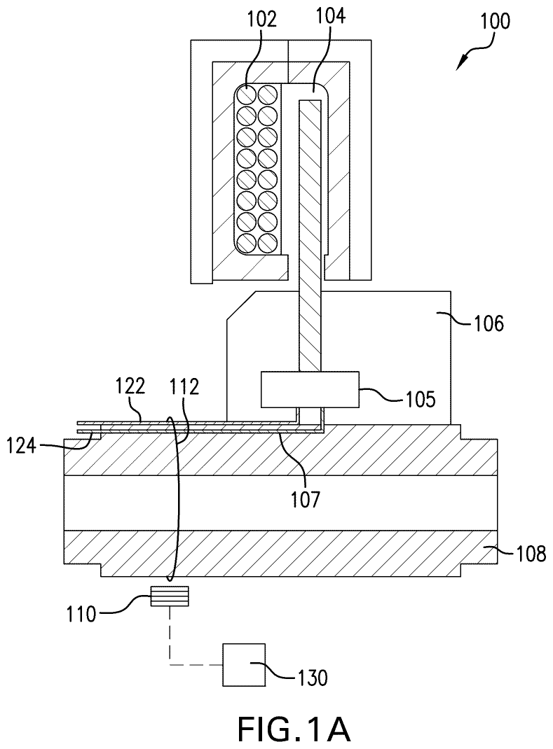

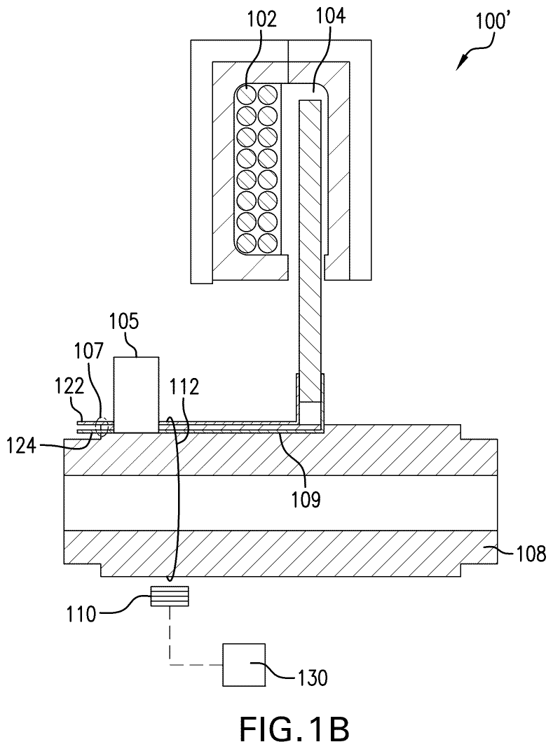

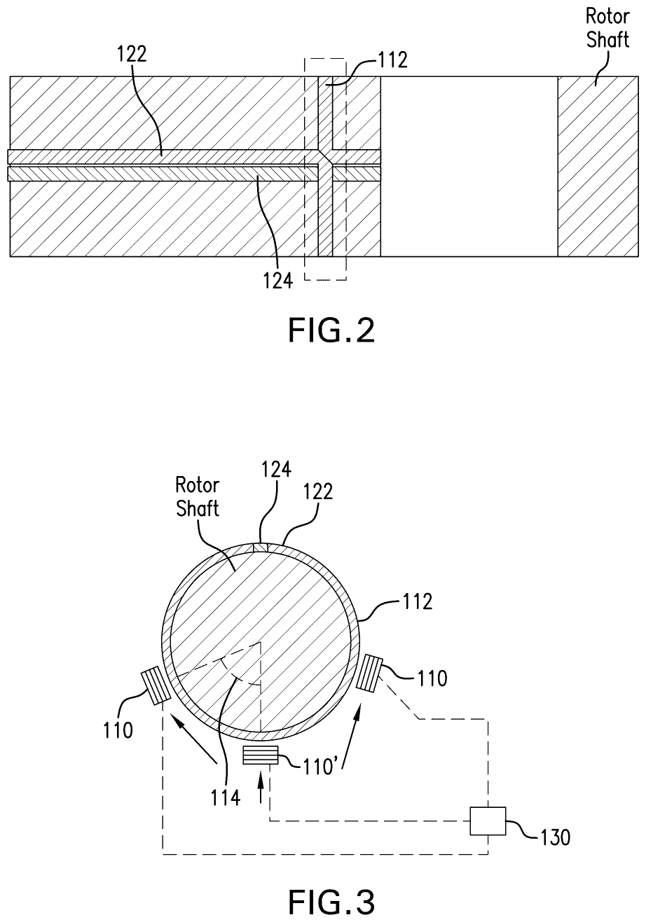

FIG. 1A illustrates a side view of a wound rotor synchronous machine (WRSM 100) including a Hall effect sensor 110 configured to directly measure a rotor current according to an example where a rectifier 140 is included within a holder 106. FIG. 1B illustrates a side view of a WRSM 100′ where a rectifier 140 is outside of the holder 106. FIG. 2 illustrates a top view of the WRSM 100 of FIG. 1. FIG. 3 illustrates an axial end view of the WRSM 100 of FIG. 1. While described herein within the context of a Hall effect sensor, it is appreciated that the systems and methods may be expanded to any contactless sensor and the Hall effect sensor 110 is provided as a non-limiting example of a contactless sensor. The example of FIG. 1B is similar in form an operation to the example of FIG. 1A. The relevant distinctions are discussed herein without providing duplicative explanation.

The WRSM 100 includes a rotary transformer primary coil 102 and a rotary transformer secondary coil 104. Direct Current (DC) is provided from a diode rectifier 105 in a holder 106. The diode rectifier 105 converts the electric energy from Alternating Current (AC) electric energy provided by the secondary coil 104 of the rotary transformer into DC electric energy. The DC electrical energy is provided to DC rotor connections 122, 124 via a pair of outputs 107 and causes the rotor to rotate according to any WRSM operation processes.

In the alternate example of FIG. 1B, the rectifier 105 is not integrated into a holder 106 (see FIG. 1A), and AC conductors 109 from the rotary transformer secondary coil 104 are passed along the shaft 108 to the rectifier 105.

Returning to the discussion of FIG. 1A, in order to measure the current provided to the rotor winding 112 of one of the DC rotor connections 122, 124 (referred to collectively as DC rotor connections 107) is wrapped around the shaft 108. The winding 112 can include any number of turns, provided the winding includes at least half of a turn. When only a single DC rotor connection 122, 124 (either DC+ or DC−) of the DC rotor connections 107 is used to create the winding, loops forming the winding 112 encircle the shaft 108 in a single direction (e.g. clockwise or counterclockwise). When both DC rotor connections 122, 124 are used to create windings, the loops forming the winding 112 encircle the shaft 108 in opposing directions (e.g., one of DC+ and DC− is wrapped clockwise and the other of DC+ and DC− is wrapped counter clockwise).

In the alternate example of FIG. 1B, the winding 112 may be formed from either the AC conductors 109 or the DC rotor connections.

Referring to both examples of FIGS. 1A and 1B, the one or more Hall effect sensors 110 are stationary relative to the shaft 108 and are disposed adjacent to winding 112. The magnetic flux generated around the winding 112 is proportional to the rotor current according to a known ratio and is detected by the Hall effect sensors(s) 110. The measured magnetic flux is communicated to a connected controller 130 and is used to compute the actual rotor current.

In some examples, the DC rotor connection 122, 124 are passed along the shaft 108 in parallel with each other and are in close proximity to each other. By running the DC rotor connections 122, 124 in parallel and in close proximity, a magnetic field produced by the portions of the DC rotor connections 122, 124 that are not included in the winding 112 is minimized and accuracy of the readings provided by the Hall effect sensor(s) 110 is improved.

In examples where multiple Hall effect sensors 110 are used (e.g. the example illustrated in the axial end view of FIG. 3), the multiple Hall effect sensors 110 are evenly distributed from a center Hall effect sensor 110′. Vibrations of the shaft 108 due to rotation can result in the shaft moving closer to one hall effect sensor 110 and further away from another Hall effect sensor 110 and the inclusion of multiple Hall effect sensors 110 allows the measured current to be averaged, thereby minimizing any impact vibration may have on the accuracy of the measurement. In the illustrated example, the Hall effect sensors 110 are separated by an angle 114 of about 120 degrees. In alternate examples, the Hall effect sensors 110 may be separated by angles 114 ranging from 110 degrees to 130 degrees. Evenly distributing the Hall effect sensors 110 further allows for variations in the sensing capabilities due to the vibration to be offset by averaging the total detected current.

While it is appreciated that any number of Hall effect sensors 110 could be utilized, each additional Hall effect sensor incorporated increases the complexity of the system while providing less benefit than each previous Hall effect sensor 110. In one example, the benefits of multiple Hall effect sensors 110 stop outweighing the complexity increase after the third Hall effect sensor 110.

In some examples, the Hall effect sensors 110 can provide a further benefit by sensing and monitoring an angular position of the rotor. An embodiment including angular position sensing and monitoring uses the magnetic field of the rotor current to detect rotation, and thus angular position, of the rotor. In alternative examples, a permanent magnet may be embedded in the shaft 108 at any suitable position. In the alternative examples, the Hall effect sensors 110 detect the angular position of the permanent magnet within the shaft 108. As the permanent magnet has a fixed position relative to the shaft 108, the angular position of the permanent magnet is the angular position of the shaft 108.

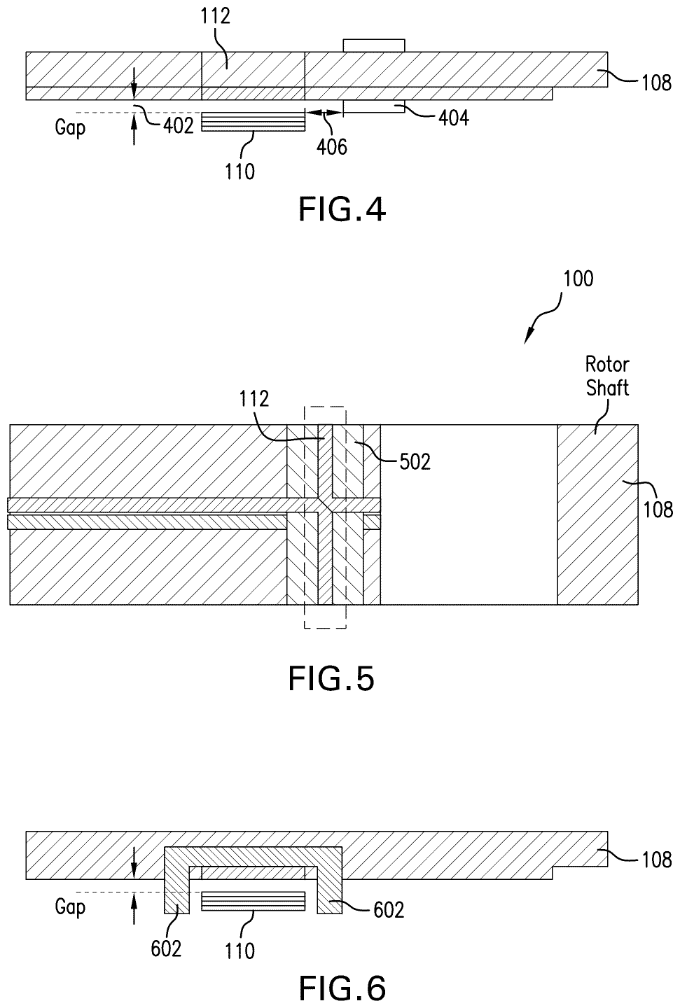

With continued reference to the example of FIGS. 1-3, FIG. 4 is partial schematic view of hall effect sensor 110 positioning relative to the rotating shaft 108. The hall effect sensor 110 is set apart from the rotating shaft 108, relative to a radius defined by the shaft 108, by a gap 402. The gap 402 is set at a minimum length that will prevent mechanical interference between the hall effect sensor 110 and the shaft 108 that may occur due to vibration of the shaft 108.

In the illustrated example, the Hall effect sensors 110 and the winding 112 are positioned axially, relative to an axis of the shaft 108, near a bearing 404 that supports the shaft 108. As used herein, near the bearing refers to a distance 406 that is less than about 5 mm. In some examples the distance can be less than about 2 mm. In yet further examples, the distance can be between about 1 mm and about 2 mm. By positioning the Hall effect sensors 110 and the winding 112 axially near the bearing 404 the amplitude of vibrations at the Hall effect sensor 110 and the winding 112 is minimized.

With continued reference to FIGS. 1-4, FIG. 5 illustrates a schematic top view of the WRSM 100 including a Hall effect sensor 110 spaced apart from the rotor using flux shielding 502. The example illustrated at FIG. 5 is generally the same structure as that shown at FIG. 2, with the addition of a high magnetic permeability shielding material 502 positioned between the winding 112 and the shaft 108. As used herein a high magnetic permeability is a permeability in the range of about 100μ to about 1000μ. In contrast, the shaft 108 has a low magnetic permeability (a magnetic permeability below about 100μ). The shielding material 502 extends axially beyond the winding 112 in each direction along the axis. The axial extension of the shielding prevents magnetic flux from wrapping around the shielding and adversely impacting the measurements taken by the Hall effect sensor(s) 110.

In some examples, the shielding 502 may include radially aligned extensions 602. The radially aligned extensions 602 protrude radially outward from the shaft 108 and provide further shielding preventing magnetic flex from wrapping around the shielding and impacting the sensor readings provided by the Hall effect sensor 110.

The use of the terms “a” and “an” and “the” and similar referents in the context of describing the invention (especially in the context of the following claims) are to be construed to cover both the singular and the plural, unless otherwise indicated herein or clearly contradicted by context. Further, it should be noted that the terms “first,” “second,” and the like herein do not denote any order, quantity, or importance, but rather are used to distinguish one element from another. The terms “about”, “substantially” and “generally” are intended to include the degree of error associated with measurement of the particular quantity based upon the equipment available at the time of filing the application. For example, “about” and/or “substantially” and/or “generally” includes a range of ±8% of a given value.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited.

What is claimed is:

1. A wound rotor synchronous machine (WRSM) comprising:
a rotary transformer having a primary coil and a secondary coil;
a rectifier connected to an output of the secondary coil via an alternating current (AC) conductor, the rectifier having a positive direct current (DC) output and a negative DC output;
a rotor connected to the positive DC output and connected to the negative DC output, the rotor including a shaft;
a winding wound around the shaft, wherein the winding comprises a turn of one of the positive DC output, the negative DC output, and the AC conductor; and
a contactless sensor disposed adjacent the winding and in communication with a controller.

2. The WRSM of claim 1, wherein the contactless sensor comprises a plurality of contactless sensors.

3. The WRSM of claim 2, wherein the controller is configured to average the outputs of the plurality of contactless sensors.

4. The WRSM of claim 2, wherein the plurality of contactless sensors are evenly spaced from a center contactless sensor.

5. The WRSM of claim 1, further comprising a magnetic shielding layer disposed between the winding and the shaft, wherein the magnetic shielding layer is constructed of a material having a magnetic permeability in the range of about 100-about 1000μ.

6. The WRSM of claim 5, wherein the magnetic shielding layer extends axially beyond the winding along the shaft in a first axial direction and in a second axial direction, opposite the first axial direction.

7. The WRSM of claim 6, wherein the magnetic shielding layer includes at least a first radially aligned extension protruding radially away from the shaft, wherein the at least the first radially aligned extension is axially adjacent to the winding.

8. The WRSM of claim 5, wherein the shaft has a magnetic permeability of less than 100μ.

9. The WRSM of claim 1, wherein the winding comprises a turn of the positive DC output and a turn of the negative DC output.

10. The WRSM of claim 9, wherein the turn of the positive DC is wound around the shaft in a first direction, and the turn of the negative DC output is wound around the shaft in a second direction opposite the first direction.

11. The WRSM of claim 1, wherein the shaft is supported by a bearing, and wherein the contactless sensor is proximate the bearing.

12. The WRSM of claim 11, wherein the contactless sensor is within 2 mm to 20 mm of the bearing.

13. The WRSM of claim 1, wherein a contactless sensor is an angular position sensor configured to sense an angular position of the shaft.

14. The WRSM of claim 1, wherein the winding includes a plurality of turns.

15. A method of detecting a rotor current of a wound rotor synchronous machine (WRSM), the method comprising:
measuring a magnetic field of a winding using a contactless sensor, wherein the winding is comprised of one of a positive direct current (DC) output of a rectifier a negative DC output of the rectifier, and an alternating current (AC) conductor connecting a secondary coil of a rotary transformer to the rectifier, wherein the winding is wound around a shaft of the WRSM.

16. The method of claim 15, wherein the contactless sensor comprises a plurality of contactless sensors, and wherein the controller is configured to calculate a rotor current using the outputs of the plurality of contactless sensors.

17. The method of claim 15, further comprising shielding the winding using a magnetic shielding layer disposed between the winding and the shaft, wherein the magnetic shielding layer is constructed of a material having a magnetic permeability in the range of about 100μ-about 1000μ.

18. The method of claim 17, wherein the magnetic shielding layer extends axially beyond the winding along the shaft in a first axial direction and in a second axial direction, opposite the first axial direction.

19. The method of claim 18, wherein the magnetic shielding layer includes at least a first radially aligned extension protruding radially away from the shaft, wherein the at least the first radially aligned extension is axially adjacent to the winding.

20. The method of claim 14, wherein the winding comprises a turn of the positive DC output and a turn of the negative DC output, and wherein the turn of the positive DC output is wound around the shaft in a first direction, and the turn of the negative DC output is wound around the shaft in a second direction opposite the first direction.
